(19) United States
(12) Patent Application Publication
(10) Pub. No.: US 2024/0375210 A1
(43) Pub. Date: Nov. 14, 2024

(54) LASER PROCESSING DEVICE AND LASER PROCESSING METHOD

(71) Applicant: HAMAMATSU PHOTONICS K.K., Hamamatsu-shi, Shizuoka (JP)

(72) Inventor: Takafumi OGIWARA, Hamamatsu-shi, Shizuoka (JP)

(73) Assignee: HAMAMATSU PHOTONICS K.K., Hamamatsu-shi, Shizuoka (JP)

(21) Appl. No.: 18/568,919

(22) PCT Filed: Jun. 15, 2022
(86) PCT No.: PCT/JP2022/024006

§ 371 Date: Dec. 11, 2023

(30) Foreign Application Priority Data
Jun. 18, 2021 (JP) 2021-101383

(51) Int. Cl. B23K 26/062

(52) U.S. Cl. CPC B23K 26/062

(57) ABSTRACT

A laser processing apparatus includes a support part, a light source, a spatial light modulator, a converging part, a moving part, and a control part. When a relative movement direction of a first converging point of first processing light and a second converging point of second processing light is set to an X direction, and a direction perpendicular to a Z direction and the X direction is set to a Y direction, the control part controls the spatial light modulator and the moving part such that the first converging point and the second converging point relatively move along a first line and a second line in the object in a state where the first converging point and the second converging point are shifted from each other in each of the X direction and the Y direction.

### TECHNICAL FIELD

The present disclosure relates to a laser processing apparatus and a laser processing method.

### BACKGROUND ART

As a laser processing apparatus that forms a modified region on an object by irradiating the object with laser light, an apparatus that modulates the laser light so that the laser light is branched into a plurality of rays of processing light and the plurality of rays of processing light are converged on different positions is known (see Patent Literatures 1 and 2, for example). In such a laser processing apparatus, a plurality of rows of modified regions can be formed by a plurality of rays of processing light. Thus, it is very effective in reducing the processing time.

### CITATION LIST

### Patent Literature

Patent Literature 1: Japanese Unexamined Patent Publication No. 2015-223620
Patent Literature 2: Japanese Unexamined Patent Publication No. 2015-226012

### SUMMARY OF INVENTION

### Technical Problem

By the way, for example, in an object including a substrate and a plurality of functional elements arranged in a matrix on the substrate, miniaturization of the functional elements has progressed. As the miniaturization of the functional element progresses, the number of lines for cutting the object for each functional element increases, and an interval between the adjacent lines becomes narrows. Thus, it is important how efficiently and accurately the modified region can be formed in the object along each of the plurality of lines.

An object of the present disclosure is to provide a laser processing apparatus and a laser processing method capable of efficiently and accurately forming a modified region in an object along each of a plurality of lines.

### Solution to Problem

According to an aspect of the present disclosure, a laser processing apparatus includes a support part configured to support an object, a light source configured to emit laser light, a spatial light modulator configured to modulate the laser light emitted from the light source, a converging part configured to converge the laser light modulated by the spatial light modulator on the object from one side in a Z direction, a moving part configured to move the converging part relative to the support part, and a control part configured to control the spatial light modulator such that the laser light is branched into first processing light and second processing light and control the moving part such that a first converging point of the first processing light and a second converging point of the second processing light relatively move along a first line and a second line in the object. When a relative movement direction of the first converging point and the second converging point is set to an X direction, and a direction perpendicular to the Z direction and the X direction is set to a Y direction, the control part controls the spatial light modulator and the moving part such that the first converging point and the second converging point relatively move along the first line and the second line in the object in a state where the first converging point and the second converging point are shifted from each other in each of the X direction and the Y direction.

In this laser processing apparatus, the first converging point of the first processing light and the second converging point of the second processing light relatively move along the first line and the second line in the object in a state where the first converging point and the second converging point are shifted from each other in each of the X direction and the Y direction. As described above, since the first converging point and the second converging point are shifted not only in the Y direction but also in the X direction, even though an interval between the first line and the second line (that is, a distance between the first line and the second line in the Y direction) becomes narrow, a distance between the first converging point and the second converging point is sufficiently secured, and deterioration of processing quality due to interference is suppressed. Therefore, according to this laser processing apparatus, it is possible to efficiently and accurately form a modified region in an object along each of a plurality of lines.

In the laser processing apparatus in the aspect of the present disclosure, the object may include a substrate and a plurality of functional elements arranged in a matrix on the substrate. In the object, a plurality of street regions may extend in a lattice shape so as to pass between the plurality of functional elements. The control part may control the spatial light modulator and the moving part such that the first converging point and the second converging point that are shifted from each other in each of the X direction and the Y direction relatively move along the first line and the second line in a state where the first line and the second line are respectively located in a first street region and a second street region adjacent to each other among the plurality of street regions. Thus, when the first line is located in the first street region and the second line is located in the second street region, it is possible to efficiently and accurately form the modified region in the object along each of the first line and the second line.

In the laser processing apparatus in the aspect of the present disclosure, the object may include a substrate and a plurality of functional elements arranged in a matrix on the substrate. In the object, a plurality of street regions may extend in a lattice shape so as to pass between the plurality of functional elements. The control part may control the spatial light modulator and the moving part such that the first converging point and the second converging point that are shifted from each other in each of the X direction and the Y direction relatively move along the first line and the second line in a state where the first line and the second line are located in each of the plurality of street regions. Thus, when the first line and the second line are located in the same street region, it is possible to efficiently and accurately form the modified region in the object along each of the first line and the second line.

The laser processing apparatus according to the aspect of the present disclosure may further include a first light blocking part. The control part may control the spatial light modulator such that the laser light is branched into 0th order light and ±nth order light (n is a natural number) including the first processing light and the second processing light. The first light blocking part may block light converged on an outside of the first processing light and the second processing light in the object among the 0th order light and the ±nth order light. Thus, it is possible to prevent damage to the object due to light converged on the outside of the first processing light and the second processing light in the object out of the 0th order light and the ±nth order light (referred to as “light branched to the outside of the first processing light and the second processing light” below).

The laser processing apparatus according to the aspect of the present disclosure may further include an adjustment optical system including a first optical element and a second optical element that function as lenses. The first optical element and the second optical element may be arranged such that a wavefront shape of the laser light in the spatial light modulator similarly coincides with a wavefront shape of the laser light in the converging part, and the first optical element and the second optical element form a bilateral telecentric optical system. The first light blocking part may be disposed on a Fourier plane between the first optical element and the second optical element. Thus, it is possible to reliably block light branched to the outside of the first processing light and the second processing light.

In the laser processing apparatus according to the aspect of the present disclosure, the first light blocking part may include a pair of first portions facing each other in the Y direction, and each of the pair of first portions may be movable along the Y direction. Thus, it is possible to adjust a distance between the pair of first portions in accordance with a shift amount between the first converging point and the second converging point in the Y direction, and to reliably block light branched to the outside of the first processing light and the second processing light.

In the laser processing apparatus according to the aspect of the present disclosure, the control part may determine the distance between the pair of first portions based on the shift amount between the first converging point and the second converging point in the Y direction, and control the first light blocking part such that the pair of first portions face each other with the determined distance in the Y direction. Thus, even when the shift amount between the first converging point and the second converging point in the Y direction is changed, it is possible to reliably block the light branched to the outside of the first processing light and the second processing light.

In the laser processing apparatus according to the aspect of the present disclosure, the first light blocking part may include a pair of second portions facing each other in the X direction. Thus, even when the shift amount between the first converging point and the second converging point in the Y direction is changed, it is possible to reliably block the light branched to the outside of the first processing light and the second processing light by making the shift amount between the first converging point and the second converging point in the X direction constant.

The laser processing apparatus according to the aspect of the present disclosure may further include a second light blocking part configured to block 0th order light and/or non-modulated light, and the second light blocking part may be movable forward and backward with respect to an optical path of the 0th order light and/or an optical path of the non-modulated light. Thus, when the 0th order light is not used as either the first processing light or the second processing light, it is possible to prevent damage to the object due to the 0th order light. In addition, it is possible to prevent the damage to the object due to the non-modulated light.

According to another aspect of the present disclosure, a laser processing method is performed in a laser processing apparatus including a support part configured to support an object, a light source configured to emit laser light, a spatial light modulator configured to modulate the laser light emitted from the light source, a converging part configured to converge the laser light modulated by the spatial light modulator on the object from one side in a Z direction, and a moving part configured to move the converging part relative to the support part. The laser processing method includes a first step of controlling the spatial light modulator such that the laser light is branched into first processing light and second processing light and a second step of controlling the moving part such that a first converging point of the first processing light and a second converging point of the second processing light relatively move along a first line and a second line in the object. In the first step, when a relative movement direction of the first converging point and the second converging point is set to an X direction, and a direction perpendicular to the Z direction and the X direction is set to a Y direction, the spatial light modulator is controlled such that the first converging point and the second converging point are shifted from each other in each of the X direction and the Y direction.

According to this laser processing method, it is possible to efficiently and accurately form a modified region in an object along each of a plurality of lines for the same reason as that of the laser processing apparatus.

### Advantageous Effects of Invention

According to the present disclosure, it is possible to provide a laser processing apparatus and a laser processing method capable of efficiently and accurately forming a modified region in an object along each of a plurality of lines.

### BRIEF DESCRIPTION OF DRAWINGS

FIG. 1 is a configuration diagram illustrating a laser processing apparatus according to an embodiment.

FIG. 2 is a cross-sectional view illustrating a portion of a spatial light modulator illustrated in FIG. 1.

FIG. 3 is a plan view illustrating a first light blocking part and a second light blocking part illustrated in FIG. 1.

FIG. 4 is a plan view illustrating an object to be processed by the laser processing apparatus illustrated in FIG. 1.

FIG. 5 is a cross-sectional view illustrating a portion of the object illustrated in FIG. 4.

FIG. 6 is a schematic diagram illustrating an irradiation state of laser light in the part of the object illustrated in FIG. 4.

FIG. 7 is a schematic diagram illustrating a positional relationship between a plurality of converging points in the part of the object illustrated in FIG. 4.

FIG. 8 is a schematic diagram illustrating a positional relationship between a plurality of converging points in the first light blocking part and the second light blocking part illustrated in FIG. 3.

FIG. 9 is a schematic diagram illustrating the positional relationship between the plurality of converging points in the first light blocking part and the second light blocking part illustrated in FIG. 3.

FIG. 10 is a flowchart illustrating a control method performed in the laser processing apparatus illustrated in FIG. 1.

FIG. 11 is a plan view illustrating a portion of the object processed by the laser processing apparatus illustrated in FIG. 1.

FIG. 12 is a table illustrating an evaluation result of a shift amount in the laser processing apparatus illustrated in FIG. 1.

FIG. 13 is a schematic diagram illustrating a positional relationship between a plurality of converging points in a part of an object to be irradiated with laser light according to a modification example.

FIG. 14 is a schematic diagram illustrating a positional relationship between a plurality of converging points in the part of the object in the modification example.

FIG. 15 is a schematic diagram illustrating the positional relationship between the plurality of converging points in the first light blocking part and the second light blocking part illustrated in FIG. 3.

### DESCRIPTION OF EMBODIMENTS

Hereinafter, embodiments of the present disclosure will be described in detail with reference to the drawings. The same or corresponding parts in the respective drawings are denoted with the same reference signs, and repetitive descriptions will be omitted.

### Configuration of Laser Processing Apparatus

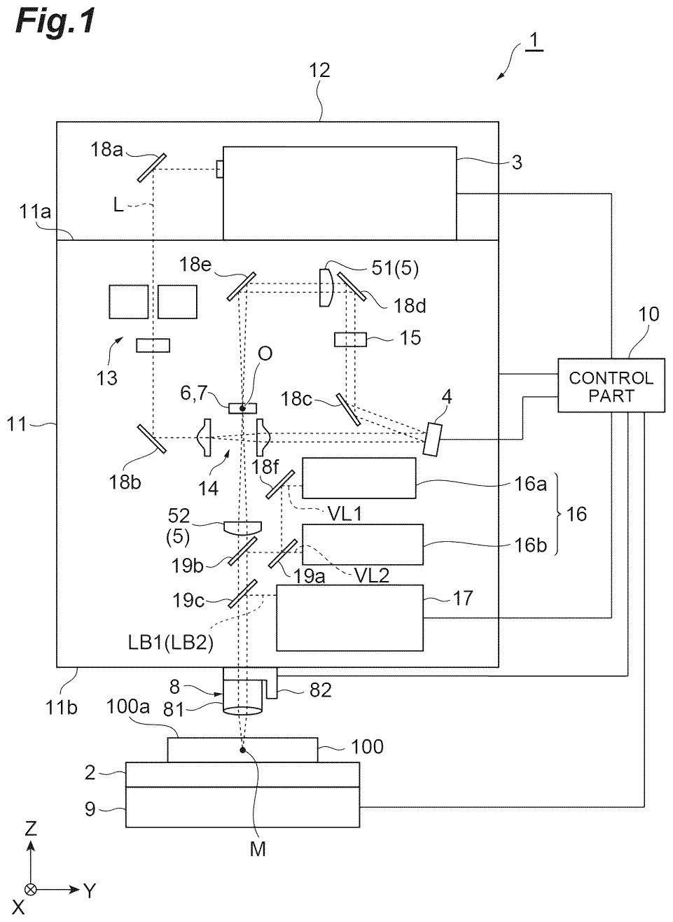

As illustrated in FIG. 1, a laser processing apparatus 1 is a device that forms a modified region M in an object 100 by irradiating the object 100 with laser light L. The laser processing apparatus 1 includes a support part 2, a light source 3, a spatial light modulator 4, an adjustment optical system 5, a first light blocking part 6, a second light blocking part 7, a converging part 8, a moving part 9, a control part 10, a housing 11, and a cover 12. The spatial light modulator 4, the adjustment optical system 5, the first light blocking part 6, and the second light blocking part 7 are disposed in the housing 11. The light source 3 is disposed on a top wall 11a of the housing 11 and is covered with the cover 12. The converging part 8 is attached to a bottom wall 11b of the housing 11. In the following description, three directions perpendicular to each other are referred to as an X direction, a Y direction, and a Z direction, respectively. In the present embodiment, the X direction is a first horizontal direction, the Y direction is a second horizontal direction perpendicular to the first horizontal direction, and the Z direction is a vertical direction.

The support part 2 is disposed below the housing 11. The support part 2 supports the object 100. As an example, the support part 2 supports the object 100 in a state where a surface 100a of the object 100 is directed to the converging part 8 side by attracting a film (not illustrated) sticking to the object 100. In the present embodiment, the support part 2 can move along the X-direction and the Y-direction, respectively, and can rotate around an axis parallel to the Z-direction as a center line.

The light source 3 emits laser light L. As an example, the light source 3 pulse-oscillates the laser light L having transparency to the object 100.

The spatial light modulator 4 modulates the laser light L emitted from the light source 3. In the present embodiment, the spatial light modulator 4 is a spatial light modulator (SLM) of reflective liquid crystal (LCOS: Liquid Crystal on Silicon), and modulates and reflects the incident laser light L.

The adjustment optical system 5 includes a first optical element 51 and a second optical element 52 that function as lenses. The first optical element 51 and the second optical element 52 are arranged such that the wavefront shape of the laser light L in the spatial light modulator 4 similarly coincides with the wavefront shape of the laser light L in the converging part 8 are similar and coincide with each other, and the first optical element 51 and the second optical element 52 form a bilateral telecentric optical system. As an example, the first optical element 51 and the second optical element 52 are arranged such that a distance of an optical path between the spatial light modulator 4 and the first optical element 51 becomes a first focal length f1 of the first optical element 51, a distance of an optical path between the converging part 8 and the second optical element 52 becomes a second focal length f2 of the second optical element 52, a distance of an optical path between the first optical element 51 and the second optical element 52 becomes a sum (that is, f1+f2) of the first focal length f1 and the second focal length f2, and the first optical element 51 and the second optical element 52 form the bilateral telecentric optical system. That is, the adjustment optical system 5 is a 4f optical system. An image of the laser light L on the reflecting surface of the spatial light modulator 4 (an image of the laser light L modulated by the spatial light modulator 4) is transferred (formed) to (on) the entrance pupil surface of the converging part 8 by the adjustment optical system 5.

The first light blocking part 6 and the second light blocking part 7 are arranged on a Fourier plane (that is, a plane including a confocal O) between the first optical element 51 and the second optical element 52. In the present embodiment, the first light blocking part 6 and the second light blocking part 7 cause only first processing light L1 and second processing light L2 to be described later to pass.

The converging part 8 converges the laser light L modulated by the spatial light modulator 4 on the object 100 (specifically, the object 100 supported by the support part 2) from the upper side (one side) in the Z direction. The converging part 8 includes a converging lens unit 81 and a drive mechanism 82. The converging lens unit 81 is configured by, for example, a plurality of lenses. The converging lens unit 81 has an entrance pupil surface to which the image of the laser light L on the reflecting surface of the spatial light modulator 4 is transferred by the adjustment optical system 5. The drive mechanism 82 is configured by, for example, a piezoelectric element. The drive mechanism 82 moves the converging lens unit 81 along the Z direction.

The moving part 9 moves the converging part 8 relative to the support part 2. The moving part 9 is a moving mechanism (including a drive source such as an actuator and a motor) that moves at least one of the converging part 8 and the support part 2 to relatively move the converging part 8 with respect to the support part 2. In the present embodiment, the moving part 9 moves the support part 2 along each of the X direction and the Y direction, rotates the support part 2 around an axis parallel to the Z direction as a center line, and moves the housing 11 along the Z direction.

The control part 10 controls the operation of each part in the laser processing apparatus 1. The control part 10 includes a processing unit, a storage unit, and an input reception unit. The processing unit is configured as a computer device including a processor, a memory, a storage, a communication device, and the like. In the processing unit, the processor executes software (program) read into the memory or the like, and controls reading and writing of data in the memory and the storage, and communication by a communication device. The storage unit is, for example, a hard disk or the like, and stores various types of data. The input reception unit is an interface unit that receives inputs of various types of data from an operator.

The laser processing apparatus 1 further includes an attenuator 13, a beam homogenizer 14, a λ/2 wavelength plate 15, a surface observation unit 16, an AF unit 17, a plurality of mirrors 18a, 18b, 18c, 18d, 18e, and 18f, and a plurality of dichroic mirrors 19a, 19b, and 19c. The mirror 18a is disposed in the cover 12. The attenuator 13, the beam homogenizer 14, the λ/2 wavelength plate 15, the surface observation unit 16, the auto-focus (AF) unit 17, the plurality of mirrors 18b, 18c, 18d, 18e, and 18f, and the plurality of dichroic mirrors 19a, 19b, and 19c are disposed in the housing 11. In the laser processing apparatus 1, laser light L emitted from the light source 3 travels in the cover 12 in the horizontal direction, is then reflected downward by the mirror 18a, and enters into the housing 11. After the light intensity of the laser light L entering into the housing 11 is adjusted by the attenuator 13, the laser light L is reflected in the horizontal direction by the mirror 18b. After the intensity distribution of the laser light L is made uniform by the beam homogenizer 14, the laser light L enters into the spatial light modulator 4. The laser light L entering into the spatial light modulator 4 is modulated by the spatial light modulator 4 and reflected obliquely upward, and then reflected upward by the mirror 18c.

The laser light L reflected by the mirror 18c is changed in polarization direction by the λ/2 wavelength plate 15, then reflected by the mirror 18d in the horizontal direction, and transmitted through the first optical element 51 of the adjustment optical system 5. The laser light L transmitted through the first optical element 51 is reflected downward by the mirror 18e. After a portion of the laser light L is blocked by the first light blocking part 6 and the second light blocking part 7, the laser light L is transmitted through the second optical element 52 of the adjustment optical system 5 and the plurality of dichroic mirrors 19b and 19c. The laser light L transmitted through the plurality of dichroic mirrors 19b and 19c is converged on the object 100 by the converging part 8.

The surface observation unit 16 is a unit for observing the object 100. The surface observation unit 16 includes an observation light source 16a and a light detector 16b. In the surface observation unit 16, visible light VL1 emitted from the observation light source 211a is reflected by the mirror 18f and the plurality of dichroic mirrors 19a and 19b. Then, the visible light VL1 is transmitted through the dichroic mirror 19c, and converged on the object 100 by the converging part 8. The reflected light VL2 of the visible light VL1 reflected by the object 100 is transmitted through the converging part 8 and the dichroic mirror 19c. After the reflected light VL2 is reflected by the dichroic mirror 19b, the reflected light VL2 is transmitted through the dichroic mirror 19a, and enters into the light detector 16b.

The AF unit 17 is a unit for finely adjusting a distance between the converging lens unit 81 of the converging part 8 and the surface 100a of the object 100. The AF unit 17 emits AF laser light LB1 and detects reflected light LB2 of the AF laser light LB1 reflected by the surface 100a of the object 100 to acquire height data of the surface 100a of the object 100. Based on the height data acquired by the AF unit 17, the control part 10 controls the drive mechanism 82 of the converging part 8 such that, for example, the distance between the converging lens unit 81 and the surface 100a of the object 100 is made constant.

### Configuration of Spatial Light Modulator

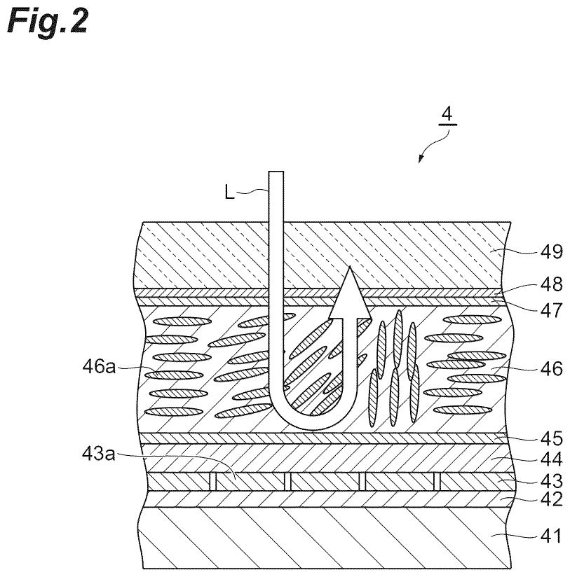

As illustrated in FIG. 2, the spatial light modulator 4 is configured by stacking a drive circuit layer 42, a pixel electrode layer 43, a reflective film 44, an alignment film 45, a liquid crystal layer 46, an alignment film 47, a transparent conductive film 48, and a transparent substrate 49 on a semiconductor substrate 41 in this order.

The semiconductor substrate 41 is, for example, a silicon substrate. The drive circuit layer 42 constitutes an active matrix circuit on the semiconductor substrate 41. The pixel electrode layer 43 includes a plurality of pixel electrodes 43a arranged in a matrix along the surface of the semiconductor substrate 41. Each pixel electrode 43a is formed of, for example, a metal material such as aluminum. A voltage is applied to each pixel electrode 43a by the drive circuit layer 42.

The reflective film 44 is, for example, a dielectric multilayer film. The alignment film 45 is provided on the surface of the liquid crystal layer 46 on the reflective film 44 side. The alignment film 47 is provided on the surface of the liquid crystal layer 46 on the opposite side of the reflective film 44. Each of the alignment films 45 and 47 is formed of, for example, a polymer material such as polyimide. A rubbing treatment is performed on a contact surface of each of the alignment films 45 and 47 with the liquid crystal layer 46. The alignment films 45 and 47 align liquid crystal molecules 46a contained in the liquid crystal layer 46 in a predetermined direction.

The transparent conductive film 48 is provided on the surface of the transparent substrate 49 on the alignment film 47 side, and faces the pixel electrode layer 43 with the liquid crystal layer 46 and the like interposed therebetween. The transparent substrate 49 is, for example, a glass substrate. The transparent conductive film 48 is formed of, for example, a light transmissive and conductive material such as ITO. The transparent substrate 49 and the transparent conductive film 48 cause the laser light L to be transmitted therethrough.

In the spatial light modulator 4 configured as described above, when a signal indicating a modulation pattern is input from the control part 10 to the drive circuit layer 42, a voltage corresponding to the signal is applied to each pixel electrode 43a. Thus, an electric field is formed between each pixel electrode 43a and the transparent conductive film 48. When the electric field is formed, in the liquid crystal layer 46, the arrangement direction of the liquid crystal molecules 46a changes for each region corresponding to each pixel electrode 43a, and the refractive index changes for each region corresponding to each pixel electrode 43a. This state is a state in which the modulation pattern is displayed on the liquid crystal layer 46.

When, in a state where the modulation pattern is displayed on the liquid crystal layer 46, the laser light L enters into the liquid crystal layer 46 from the outside through the transparent substrate 49 and the transparent conductive film 48, is reflected by the reflective film 44, and then is emitted to the outside from the liquid crystal layer 46 through the transparent conductive film 48 and the transparent substrate 49, the laser light L is modulated in accordance with the modulation pattern displayed on the liquid crystal layer 46. As described above, according to the spatial light modulator 4, it is possible to modulate (for example, modulation of intensity, amplitude, phase, polarization, and the like of the laser light L) the laser light L by appropriately setting the modulation pattern to be displayed on the liquid crystal layer 46.

### First Light Blocking Part and Second Light Blocking Part

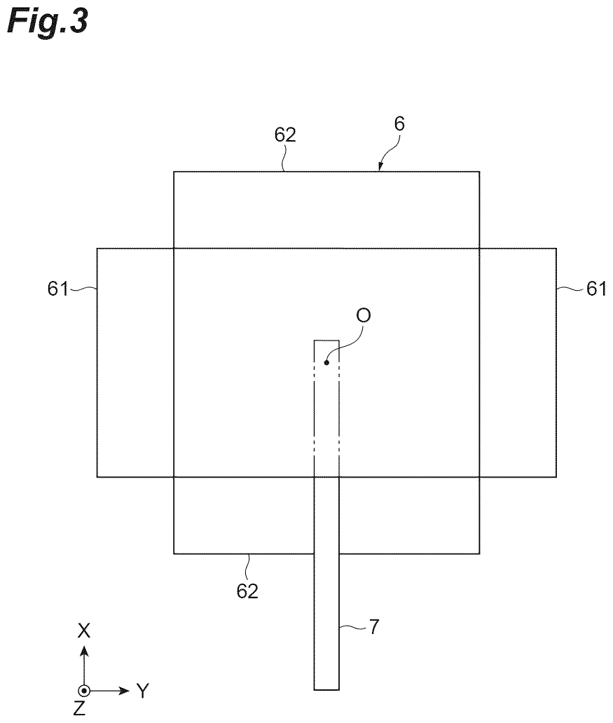

As illustrated in FIG. 3, the first light blocking part 6 includes a pair of first portions 61 and a pair of second portions 62. The pair of first portions 61 faces each other in the Y direction. In the present embodiment, the pair of first portions 61 faces each other in the Y direction with the confocal O interposed therebetween, on the Fourier plane between the first optical element 51 and the second optical element 52. Each of the first portions 61 is movable along the Y direction. Each of the first portions 61 is moved along the Y direction by the drive source (not illustrated) such as a motor, which is controlled by the control part 10. The pair of second portions 62 faces each other in the X direction. In the present embodiment, the pair of second portions 62 faces each other in the X direction with the confocal O interposed therebetween, on the Fourier plane between the first optical element 51 and the second optical element 52. Each of the second portions 62 is fixed in a state where a distance between the pair of second portions 62 is constant.

For example, when the laser light L is diffracted into 0th order light and ±nth order light (n is a natural number) by the spatial light modulator 4, the second light blocking part 7 can move forward and backward with respect to an optical path of the 0th order light and an optical path of the non-modulated light, and blocks the 0th order light and the non-modulated light in a state of being located on the optical path. In the present embodiment, the second light blocking part 7 can move forward and backward with respect to the confocal O on the Fourier plane between the first optical element 51 and the second optical element 52, and blocks the 0th order light and the non-modulated light in a state of being located on the confocal O. The second light blocking part 7 is moved forward and backward by the drive source (not illustrated) such as a motor, which is controlled by the control part 10. In the present embodiment, the second light blocking part 7 is an elongated member that extends along the X direction and can move forward and backward along the X direction, but may be an elongated member that extends along another direction (for example, in the Y direction or the like) and can move forward and backward along the other direction. Note that the non-modulated light is light emitted from the spatial light modulator 4 without being modulated by the spatial light modulator 4 among rays of the laser light L entering into the spatial light modulator 4. For example, light reflected by the outer surface of the transparent substrate 49 (surface opposite to the transparent conductive film 48) among rays of the laser light L entering into the spatial light modulator 4 becomes the non-modulated light.

### Configuration of Object

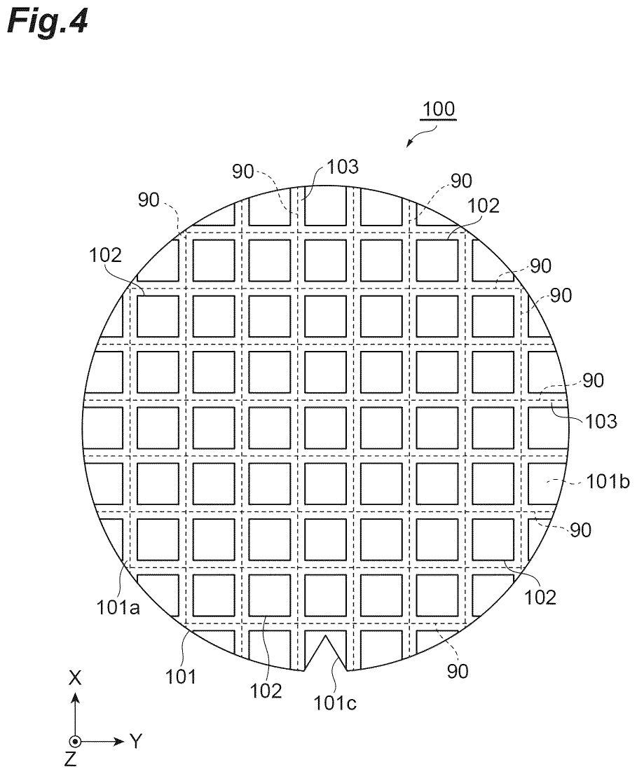

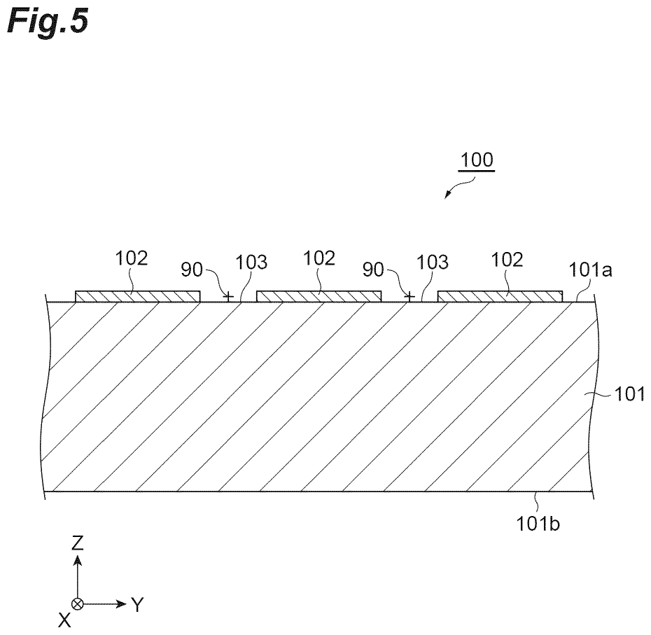

As illustrated in FIGS. 4 and 5, the object 100 includes a substrate 101 and a plurality of functional elements 102. The plurality of functional elements 102 is arranged in a matrix on the substrate 101.

The substrate 101 has a front surface 101a and a back surface 101b. The substrate 101 is, for example, a semiconductor substrate such as a silicon substrate. A notch 101c indicating a crystal orientation is provided in the substrate 101. Note that the substrate 101 may be provided with an orientation flat instead of the notch 101c.

The plurality of functional elements 102 is provided on the front surface 101a of the substrate 101. Each of the functional elements 102 is, for example, a light receiving element such as a photodiode, a light emitting element such as a laser diode, a circuit element such as a memory, or the like. Each of the functional elements 102 may be configured three-dimensionally by stacking a plurality of layers.

In the object 100, a plurality of street regions 103 extend in a lattice shape so as to pass between the plurality of functional elements 102. In the present embodiment, a plurality of lines 90 are set in the object 100 such that one line 90 is located in one street region 103, and the object 100 is cut for each functional element 102 along each of the plurality of lines 90. As an example, each line 90 passes through the center of the street region 103. In the present embodiment, the plurality of lines 90 are virtual lines set in the object 100 by the laser processing apparatus 1, but may be lines actually drawn in the object 100. Note that the point that one or a plurality of lines 90 are located in one street region 103 means that one or a plurality of lines 90 extend along the one street region 103 in the one street region 103 when viewed from the Z direction.

### Function of Control Part

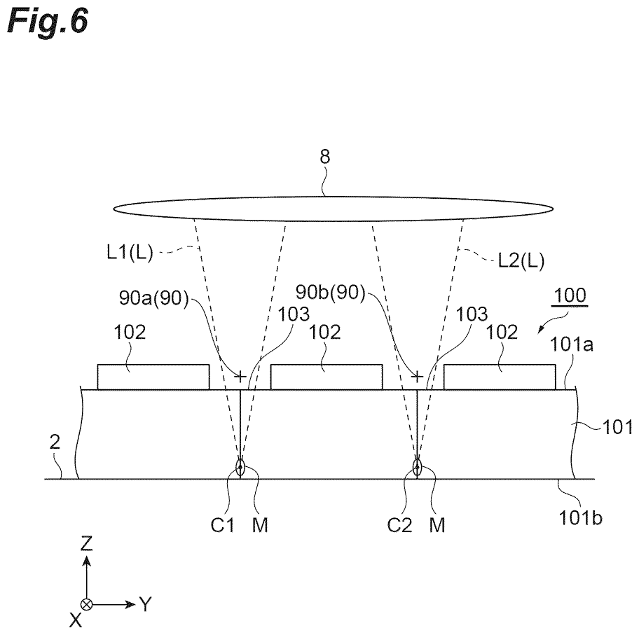

As illustrated in FIG. 6, the object 100 is supported by the support part 2 such that the laser light L enters to the substrate 101 from the plurality of functional elements 102 side (that is, the laser light L enters to the substrate 101 from a region corresponding to the street region 103 in the front surface 101a of the substrate 101). The function of the control part 10 will be described focusing on a first line 90a and a second line 90b adjacent to each other among the plurality of lines 90. Note that the control part 10 similarly functions for all the lines 90 with the first line 90a and the second line 90b adjacent to each other as the minimum unit. Furthermore, the control part 10 similarly functions even when the object 100 is supported by the support part 2 such that the laser light L enters to the substrate 101 from the side opposite to the plurality of functional elements 102 (that is, the laser light L enters to the substrate 101 from the back surface 101b of the substrate 101).

As illustrated in FIGS. 1 and 6, the control part 10 controls the moving part 9 such that the support part 2 rotates around the axis parallel to the Z direction as the center line. As a result, the first line 90a and the second line 90b extend along the X direction and are adjacent to each other in the Y direction. In this state, the control part 10 controls the spatial light modulator 4 such that the laser light L is branched into the first processing light L1 and the second processing light L2 (first step), and controls the moving part 9 such that a first converging point C1 of the first processing light L1 and a second converging point C2 of the second processing light L2 relatively move along the first line 90a and the second line 90b in the object 100 (second step). At this time, based on the height data acquired by the AF unit 17, the control part 10 controls the drive mechanism 82 of the converging part 8 such that each of the first converging point C1 and the second converging point C2 is located at a predetermined depth from the front surface 101a. With the above description, a modified region M is formed inside the substrate 101 along each of the first line 90a and the second line 90b.

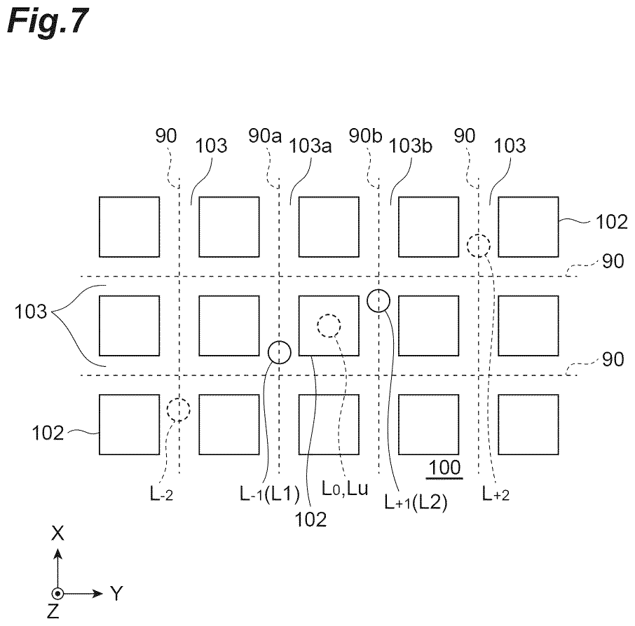

Branching the laser light L will be described in more detail. As illustrated in FIG. 7, the control part 10 controls the spatial light modulator 4 such that the laser light L is branched into 0th order light L₀ and ±nth order light L_{±n} (n is a natural number) including the first processing light L1 and the second processing light L2. A plurality of converging points of the ±nth order light L_{±n} are arranged at equal intervals on one straight line inclined with respect to both the X direction and the Y direction in the object 100. The converging point of the 0th order light L₀ and the converging point of the non-modulated light Lu are located at an intermediate point between the converging point of (−1)th order light L₋₁ and the converging point of (+1)th order light L₊₁ in the object 100. In the present embodiment, the first processing light L1 is (−1)th order light L₋₁, and the second processing light L2 is (+1)th order light L₊₁. Therefore, the first converging point C1 of the first processing light L1 and the second converging point C2 of the second processing light L2 (see FIG. 6) are shifted from each other in each of the Y direction and the X direction.

That is, the control part 10 controls the spatial light modulator 4 and the moving part 9 such that the first converging point C1 and the second converging point C2 relatively move along the first line 90a and the second line 90b in the object 100 in a state where the first converging point C1 and the second converging point C2 are shifted from each other in each of the X direction and the Y direction. In the present embodiment, the control part 10 controls the spatial light modulator 4 and the moving part 9 such that the first converging point C1 and the second converging point C2 shifted from each other in each of the X direction and the Y direction relatively move along the first line 90a and the second line 90b in a state in which the first line 90a and the second line 90b are respectively located in a first street region 103a and a second street region 103b adjacent to each other among a plurality of street regions 103.

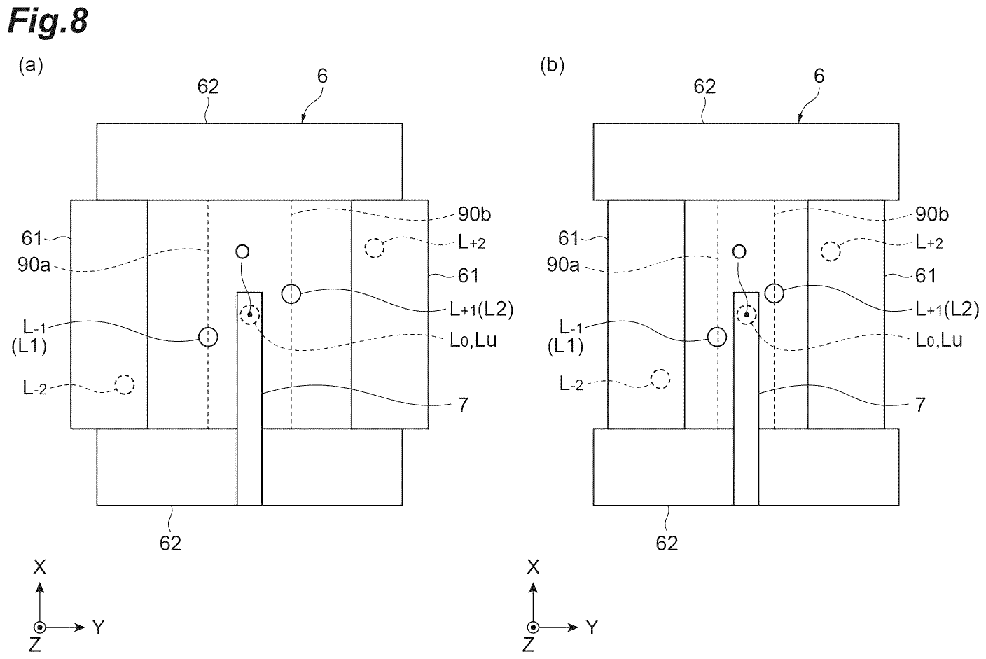

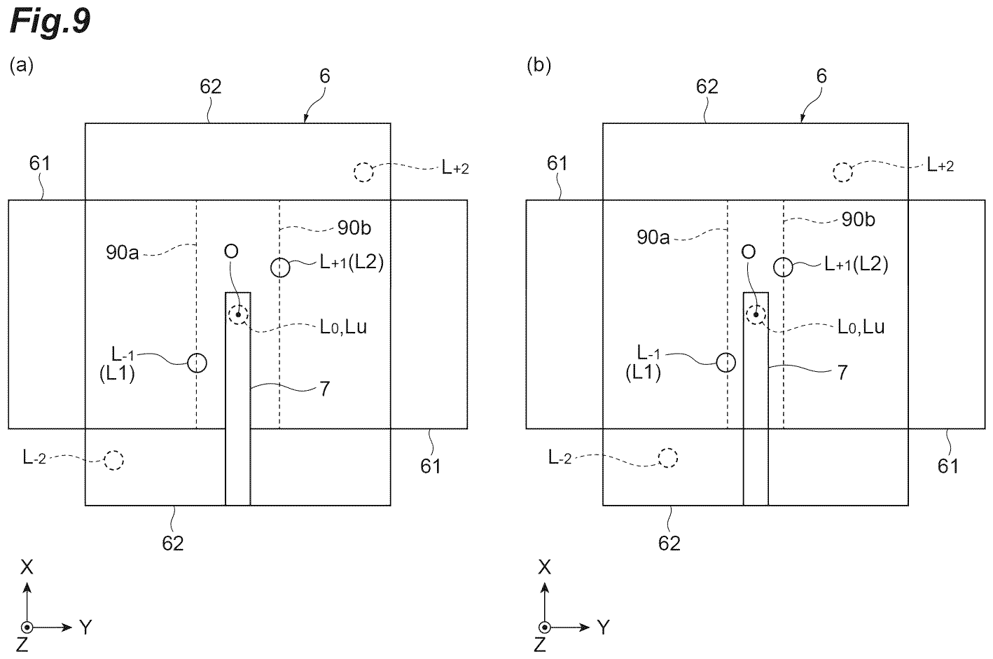

Furthermore, as illustrated in FIGS. 8 and 9, the control part 10 controls the first light blocking part 6 to block light converged on the outside of the first processing light L1 and the second processing light L2 in the object 100 among the 0th order light L₀ and ±nth order light L_{±n}, and controls the second light blocking part 7 to block the 0th order light L₀ and the non-modulated light Lu. In the present embodiment, since the first processing light L1 is the (−1)th order light L₋₁ and the second processing light L2 is the (+1)th order light L₊₁, ±mth order light (m is a natural number of 2 or more) including (−2)th order light L₋₂ and (+2)th order light L₊₂ is blocked by the first light blocking part 6.

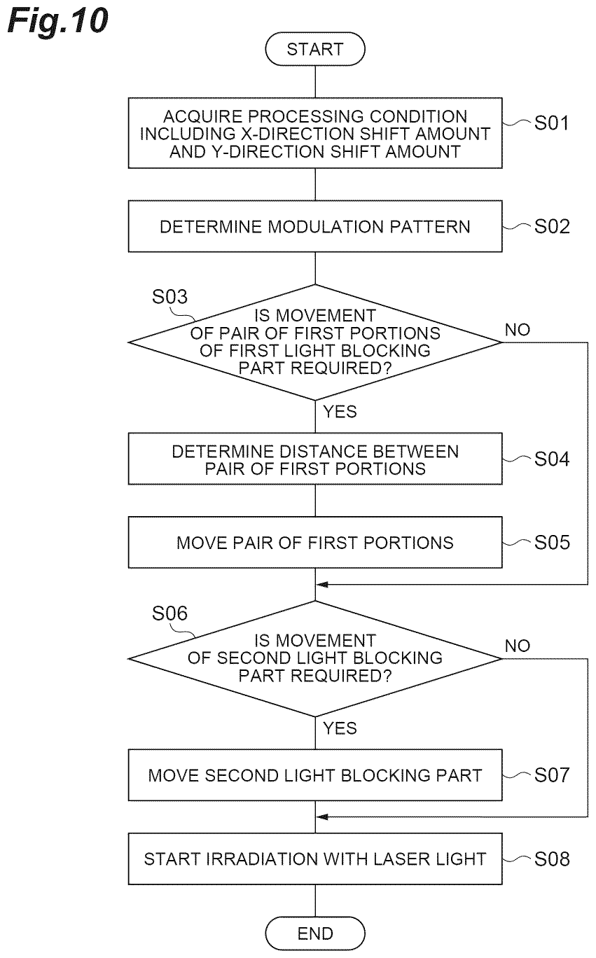

The control of the first light blocking part 6 and the second light blocking part 7 by the control part 10 will be described in more detail with reference to FIG. 10. First, the control part 10 acquires processing conditions including an X-direction shift amount (shift amount between the first converging point C1 and the second converging point C2 in the X direction) and a Y-direction shift amount (shift amount between the first converging point C1 and the second converging point C2 in the Y direction) (S01 in FIG. 10). Then, the control part 10 determines a modulation pattern to be input to the spatial light modulator 4 (S02 in FIG. 10).

Subsequently, the control part 10 determines whether or not the movement of the pair of first portions 61 of the first light blocking part 6 is required, based on the acquired X-direction shift amount and Y-direction shift amount (S03 in FIG. 10). For example, as illustrated in

FIG. 8, when the first processing light L1 is the (−1)th order light L₋₁ and the second processing light L2 is the (+1)th order light L₊₁, and it is assumed that the (−2)th order light L₋₂ and the (+2)th order light L₊₂ are not blocked by the pair of second portions 62 of the first light blocking part 6, the control part 10 determines that the movement of the pair of first portions 61 is required. On the other hand, as illustrated in FIG. 9, when the first processing light L1 is the (−1)th order light L₋₁ and the second processing light L2 is the (+1)th order light L₊₁, and it is assumed that the (−2)th order light L₋₂ and the (+2)th order light L₊₂ are blocked by the pair of second portions 62 of the first light blocking part 6, the control part 10 determines that the movement of the pair of first portions 61 is not required.

When determining that the movement of the pair of first portions 61 is required, the control part 10 determines the distance between the pair of first portions 61 based on the Y-direction shift amount (S04 in FIG. 10). In addition, the control part 10 controls the first light blocking part 6 such that the pair of first portions 61 faces each other in the Y direction with the determined distance (S05 in FIG. 10). As described above, since the plurality of converging points of ±nth order light L_{±n} are arranged at equal intervals on one straight line inclined with respect to both the X direction and the Y direction in the object 100, the control part 10 can determine the distance between the pair of first portions 61 such that ±mth order light (m is a natural number of 2 or more) including the (−2)th order light L₋₂ and the (+2)th order light L₊₂ is blocked by the first portion 61 based on the Y-direction shift amount. On the other hand, when determining that the movement of the pair of first portions 61 is not required, the control part 10 skips the processes of S04 and S05 in FIG. 10.

Subsequently, the control part 10 determines whether or not the movement of the second light blocking part 7 is required, based on the acquired processing conditions (S06 in FIG. 10). For example, as illustrated in FIGS. 8 and 9, when the first processing light L1 is the (−1)th order light L₋₁ and the second processing light L2 is the (+1)th order light L₊₁, it is not necessary to irradiate the object 100 with the 0th order light L₀ and the non-modulated light Lu. Thus, the control part 10 determines that the movement of the second light blocking part 7 is required. On the other hand, when the first processing light L1 or the second processing light L2 is the 0th order light L₀, the control part 10 determines that the movement of the second light blocking part 7 is not required.

When determining that the movement of the second light blocking part 7 is required, the control part 10 controls the second light blocking part 7 such that the 0th order light L₀ and the non-modulated light Lu are blocked (S07 in FIG. 10). On the other hand, when determining that the movement of the second light blocking part 7 is not required, the control part 10 skips the process of S07 in FIG. 10.

Subsequently, the control part 10 starts irradiation with the laser light L (S08 in FIG. 10). That is, the control part 10 controls the light source 3 to emit the laser light L and controls the spatial light modulator 4 and the moving part 9 such that the first converging point C1 and the second converging point C2 relatively move along the first line 90a and the second line 90b in the object 100 in a state where the first converging point C1 and the second converging point C2 are shifted from each other in each of the X direction and the Y direction.

### X-Direction Shift Amount and Y-Direction Shift Amount

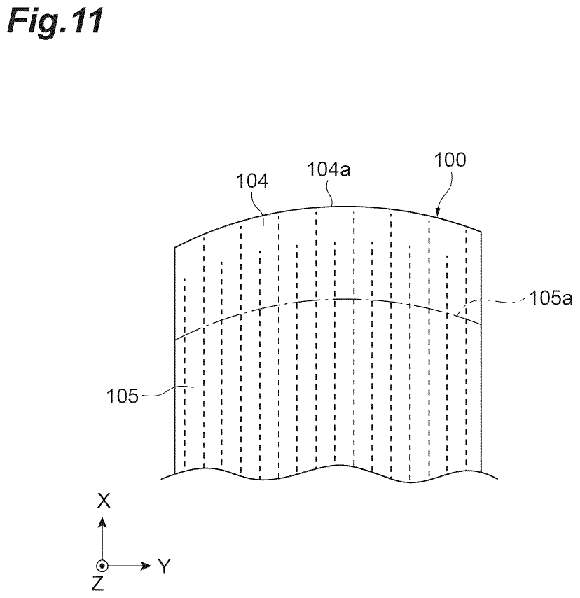

FIG. 11 is a plan view illustrating a portion of the object 100 processed by the laser processing apparatus 1. As illustrated in FIG. 11, focusing on a plurality of modified regions M extending in one direction in the object 100, an outer end portion of the modified region M (an end portion of the object 100 on an outer edge 104a side) is located in the outer edge portion 104 of the object 100. In the plurality of modified regions M extending in one direction, the modified region M in which a distance in the X direction from the outer edge 104a to the outer end portion of the modified region M is a first distance and the modified region M in which the distance in the X direction from the outer edge 104a to the outer end portion of the modified region M is a second distance greater than the first distance are arranged periodically (for example, alternately). This is because the relative movement of the first converging point C1 and the second converging point C2 shifted from each other in each of the X direction and the Y direction, along the first line 90a and the second line 90b, is similarly performed for all the lines 90 with the first line 90a and second line 90b adjacent to each other as the minimum unit, as described above. Here, the X-direction shift amount is preferably smaller than the width of the outer edge portion 104 surrounding an effective portion 105 in which the plurality of functional elements 102 is formed (the width of the outer edge 104a in the normal direction). As a result, it is possible to form all the modified regions M to intersect with an outer edge 105a of the effective portion 105.

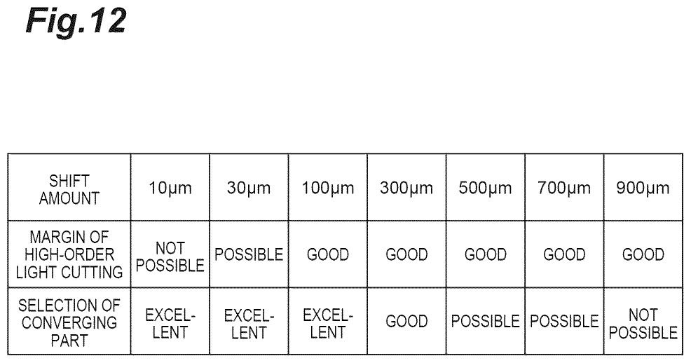

FIG. 12 is a table illustrating an evaluation result of the shift amount in the laser processing apparatus 1. The “shift amount” in FIG. 12 means each of the X-direction shift amount and the Y-direction shift amount. As illustrated in FIG. 12, each of the X-direction shift amount and the Y-direction shift amount is preferably 30 μm or more and 900 μm or less, and more preferably 100 μm or more and 900 μm or less from the viewpoint of a margin of high-order light cutting (reliable passage of only the first processing light L1 and the second processing light L2 among the 0th order light L₀ and ±nth order light L_{±n}, in other words, reliable blocking of only the light converged on the outside of the first processing light L1 and the second processing light L2 in the object 100 among the 0th order light L₀ and ±nth order light L_{±n}). In addition, each of the X-direction shift amount and the Y-direction shift amount is preferably 10 μm or more and 700 μm or less, and more preferably 10 μm or more and 300 μm or less, from the viewpoint of selection of the converging part 8 (the limit of the maximum value of the pupil diameter of the converging part 8 that may realize NA for suitably forming the modified region M). Thus, each of the X-direction shift amount and the Y-direction shift amount is preferably 30 μm or more and 700 μm or less, and more preferably 100 μm or more and 300 μm or less.

### Actions and Effects

In the laser processing apparatus 1 and the laser processing method performed in the laser processing apparatus 1, the first converging point C1 of the first processing light L1 and the second converging point C2 of the second processing light L2 relatively move along the first line 90a and the second line 90b in the object 100 in a state where the first converging point C1 and the second converging point C2 are shifted from each other in each of the X direction and the Y direction. As described above, since the first converging point C1 and the second converging point C2 are shifted not only in the Y direction but also in the X direction, even though the interval between the first line 90a and the second line 90b (that is, a distance between the first line 90a and the second line 90b in the Y direction) becomes narrow, the distance between the first converging point C1 and the second converging point C2 is sufficiently secured, and deterioration of processing quality due to interference is suppressed. Therefore, according to the laser processing apparatus 1, it is possible to efficiently and accurately form the modified region M in the object 100 along each of the plurality of lines 90.

In the laser processing apparatus 1, the control part 10 controls the spatial light modulator 4 and the moving part 9 such that the first converging point C1 and the second converging point C2 shifted from each other in each of the X direction and the Y direction relatively move along the first line 90a and the second line 90b in a state in which the first line 90a and the second line 90b are respectively located in a first street region 103a and a second street region 103b adjacent to each other among a plurality of street regions 103. As a result, when the first line 90a is located in the first street region 103a and the second line 90b is located in the second street region 103b, it is possible to efficiently and accurately form the modified region M in the object 100 along each of the first line 90a and the second line 90b.

In the laser processing apparatus 1, the control part 10 controls the spatial light modulator 4 such that the laser light L is branched into 0th order light L₀ and +nth order light L_{±n} including the first processing light L1 and the second processing light L2, and the first light blocking part 6 blocks the light converged on the outside of the first processing light L1 and the second processing light L2 in the object 100 among the 0th order light L₀ and ±nth order light L_{±n}. Thus, it is possible to prevent damage to the object 100 due to light converged on the outside of the first processing light L1 and the second processing light L2 in the object 100 among the 0th order light L₀ and the ±nth order light L_{±n} (referred to as “light branched to the outside of the first processing light L1 and the second processing light L2” below).

In the laser processing apparatus 1, the first light blocking part 6 is disposed on the Fourier plane between the first optical element 51 and the second optical element 52. As a result, it is possible to reliably block light branched to the outside of the first processing light L1 and the second processing light L2.

In the laser processing apparatus 1, the first light blocking part 6 has a pair of first portions 61 facing each other in the Y direction, and the pair of first portions 61 is movable along the Y direction. As a result, it is possible to adjust the distance between the pair of first portions 61 in accordance with the Y-direction shift amount between the first converging point C1 and the second converging point C2, and to reliably block light branched to the outside of the first processing light L1 and the second processing light L2.

In the laser processing apparatus 1, the control part 10 determines the distance between the pair of first portions 61 based on the Y-direction shift amount between the first converging point C1 and the second converging point C2, and controls the first light blocking part 6 such that the pair of first portions 61 faces each other in the Y direction with the determined distance. As a result, even when the Y-direction shift amount between the first converging point C1 and the second converging point C2 is changed, it is possible to reliably block the light branched to the outside of the first processing light L1 and the second processing light L2.

In the laser processing apparatus 1, the first light blocking part 6 has a pair of second portions 62 facing each other in the X direction. As a result, even when the Y-direction shift amount between the first converging point C1 and the second converging point C2 is changed, for example, by making the X-direction shift amount between the first converging point C1 and the second converging point C2 constant, it is possible to reliably block the light branched to the outside of the first processing light L1 and the second processing light L2.

In the laser processing apparatus 1, the second light blocking part 7 that blocks the 0th order light L₀ and the non-modulated light Lu can move forward and backward with respect to the optical path of the 0th order light L₀ and the optical path of the non-modulated light Lu. As a result, when the 0th order light L₀ is not used as either the first processing light L1 or the second processing light L2, it is possible to prevent the damage to the object 100 due to the 0th order light L₀. In addition, it is possible to prevent the damage to the object 100 due to the non-modulated light Lu.

### Modification Examples

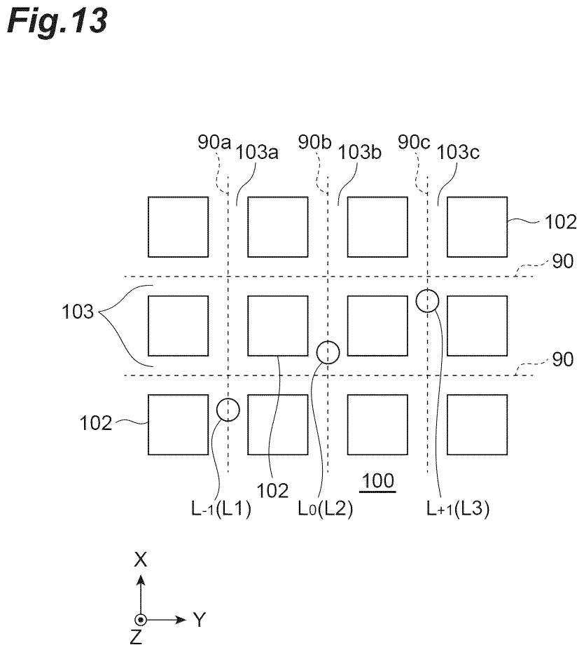

The present disclosure is not limited to the above embodiment. For example, as illustrated in FIG. 13, the control part 10 may control the spatial light modulator 4 such that laser light L is branched into first processing light L1, second processing light L2, and third processing light L3, and control the moving part 9 such that a first converging point of the first processing light L1, a second converging point of the second processing light L2, and a converging point of the third processing light L3 relatively move along a first line 90a, a second line 90b, and a third line 90c in the object 100. That is, the control part 10 may control the spatial light modulator 4 such that the laser light L is branched into a plurality of rays of light including a plurality of rays of processing light, and control the moving part 9 such that a plurality of converging points of the plurality of rays of processing light relatively move along a plurality of lines in the object 100.

In the example illustrated in FIG. 13, the first processing light L1 is (−1)th order light L₋₁, the second processing light L2 is 0th order light L₀, and the third processing light L3 is (+1)th order light L₊₁. Also in this example, the control part 10 controls the spatial light modulator 4 and the moving part 9 such that the first converging point of the first processing light L1, the second converging point of the second processing light L2, and the converging point of the third processing light L3 relatively move along the first line 90a, the second line 90b, and the third line 90c in the object 100 in a state where the first converging point of the first processing light L1 and the second converging point of the second processing light L2 are shifted from each other in the X direction and the Y direction, and the second converging point of the second processing light L2 and the third converging point of the third processing light L3 are shifted from each other in the X direction and the Y direction.

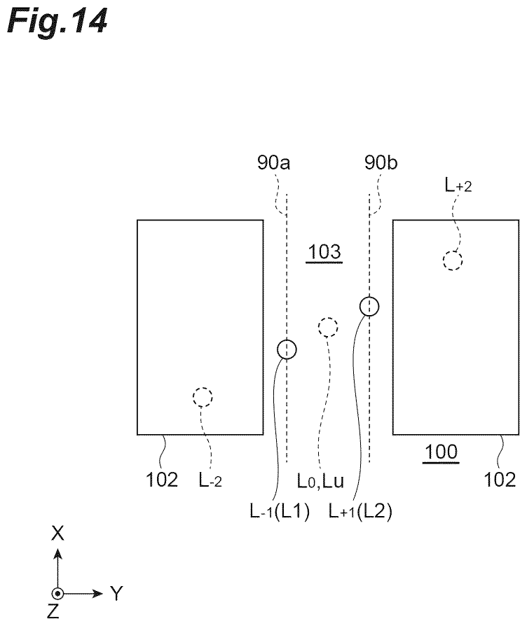

As illustrated in FIG. 14, the control part 10 may control the spatial light modulator 4 and the moving part 9 such that the first converging point C1 and the second converging point C2 shifted from each other in each of the X direction and the Y direction relatively move along the first line 90a and the second line 90b in a state where the first line 90a and the second line 90b are located in each of a plurality of street regions 103 (that is, the first line 90a and the second line 90b are located with respect to one street region 103). As a result, when the first line 90a and the second line 90b are located in the same street region 103, it is possible to efficiently and accurately form the modified region M in the object 100 along each of the first line 90a and the second line 90b. Also in this case, among the 0th order light L₀ and ±nth order light L_{±n}, the light converged on the outside of the first processing light L1 and the second processing light L2 in the object 100 may be blocked by the first light blocking part 6. In addition, also in this case, the 0th order light L₀ and the non-modulated light Lu may be blocked by the second light blocking part 7.

The first light blocking part 6 and the second light blocking part 7 are not limited to the case of being disposed on the Fourier plane between the first optical element 51 and the second optical element 52. For example, the first light blocking part 6 and the second light blocking part 7 may be disposed immediately before the entrance pupil surface of the converging part 8.

In the first light blocking part 6, each of the first portions 61 may be fixed in a state where the distance between the pair of first portions 61 is constant. In this case, the shift amount between the first converging point C1 and the second converging point C2 in the X direction may be adjusted within the range of the distance between the pair of first portions 61. In the first light blocking part 6, each of the second portions 62 may be movable in the X direction. The first light blocking part 6 may have the pair of first portions 61 and may not have the pair of second portions 62. The first light blocking part 6 may have the pair of second portions 62 and may not have the pair of first portions 61. For example, when the optical path of the 0th order light is shifted from the optical path of the non-modulated light, the second light blocking part 7 may block at least one of the 0th order light and the non-modulated light.

The first line 90a and the second line 90b are not limited to those extending along a predetermined straight line, and may extend along a predetermined curve. When the first line 90a and the second line 90b extend along a predetermined curve, the relative movement direction in which the first converging point C1 and the second converging point C2 relatively move along the first line 90a and the second line 90b is a tangential direction of the curve.

In the above embodiment, the X direction is a first horizontal direction, the Y direction is a second horizontal direction perpendicular to the first horizontal direction, and the Z direction is the vertical direction.

Each of the X direction, the Y direction, and the Z direction is not limited to each of these directions. For example, the Z direction may be a direction intersecting with the vertical direction.

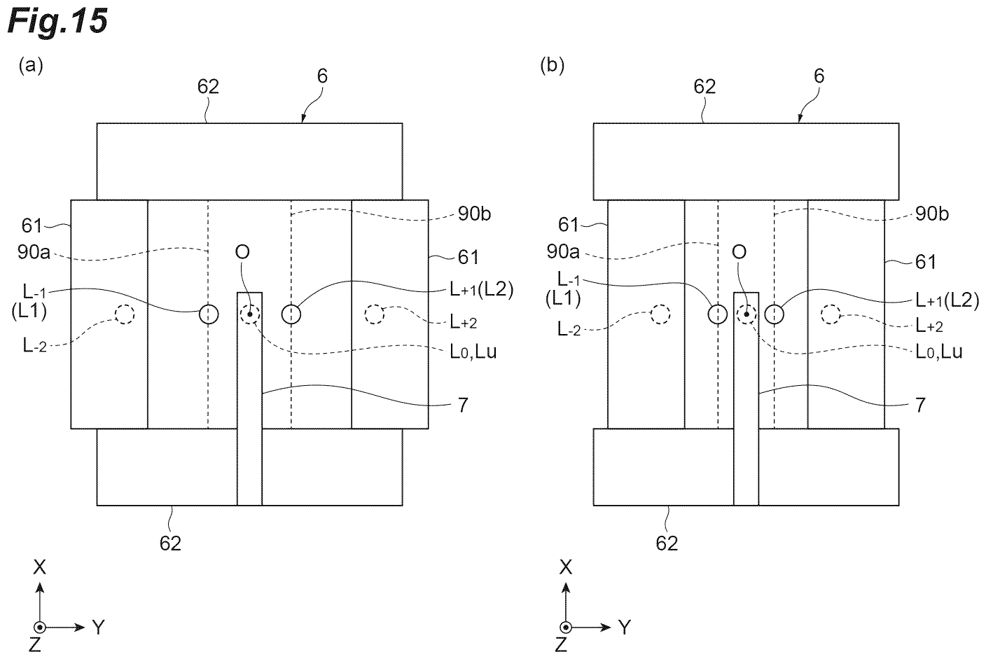

As illustrated in FIG. 15, the control part 10 may control the spatial light modulator 4 and the moving part 9 such that the first converging point and the second converging point relatively move along the first line and the second line in the object in a state where the first converging point C1 and the second converging point C2 are shifted from each other at least in the Y direction. Also in this case, among the 0th order light L₀ and ±nth order light L_{±n}, the light converged on the outside of the first processing light L1 and the second processing light L2 in the object 100 may be blocked by the first light blocking part 6. In addition, also in this case, the 0th order light L₀ and the non-modulated light Lu may be blocked by the second light blocking part 7.

### REFERENCE SIGNS LIST

1 laser processing apparatus
2 support part
3 light source
4 spatial light modulator
5 adjustment optical system
6 first light blocking part
7 second light blocking part
8 converging part
9 moving part
10 control part
51 first optical element
52 second optical element
61 first portion
62 second portion
90 line
90a first line
90b second line
100 object
101 substrate
102 functional element
103 street region
103a first street region
103b second street region
C1 first converging point
C2 second converging point
L laser light
L1 first processing light
L2 second processing light
L₀ 0th order light
L_{±n} ±nth order light
Lu non-modulated light
M modified region

1. A laser processing apparatus comprising:
a support part configured to support an object;
a light source configured to emit laser light;
a spatial light modulator configured to modulate the laser light emitted from the light source;
a converging part configured to converge the laser light modulated by the spatial light modulator on the object from one side in a Z direction;
a moving part configured to move the converging part relative to the support part; and
a control part configured to control the spatial light modulator such that the laser light is branched into first processing light and second processing light and control the moving part such that a first converging point of the first processing light and a second converging point of the second processing light relatively move along a first line and a second line in the object, wherein
when a relative movement direction of the first converging point and the second converging point is set to an X direction, and a direction perpendicular to the Z direction and the X direction is set to a Y direction,
the control part controls the spatial light modulator and the moving part such that the first converging point and the second converging point relatively move along the first line and the second line in the object in a state where the first converging point and the second converging point are shifted from each other in each of the X direction and the Y direction.

2. The laser processing apparatus according to claim 1, wherein
the object includes a substrate and a plurality of functional elements arranged in a matrix on the substrate,
in the object, a plurality of street regions extend in a lattice shape so as to pass between the plurality of functional elements, and
the control part controls the spatial light modulator and the moving part such that the first converging point and the second converging point that are shifted from each other in each of the X direction and the Y direction relatively move along the first line and the second line in a state where the first line and the second line are respectively located in a first street region and a second street region adjacent to each other among the plurality of street regions.

3. The laser processing apparatus according to claim 1, wherein
the object includes a substrate and a plurality of functional elements arranged in a matrix on the substrate,
in the object, a plurality of street regions extend in a lattice shape so as to pass between the plurality of functional elements, and
the control part controls the spatial light modulator and the moving part such that the first converging point and the second converging point that are shifted from each other in each of the X direction and the Y direction relatively move along the first line and the second line in a state where the first line and the second line are located in each of the plurality of street regions.

4. The laser processing apparatus according to claim 1, further comprising:
a first light blocking part, wherein
the control part controls the spatial light modulator such that the laser light is branched into 0th order light and ±nth order light (n is a natural number) including the first processing light and the second processing light, and
the first light blocking part blocks light converged on an outside of the first processing light and the second processing light in the object among the 0th order light and the ±nth order light.

5. The laser processing apparatus according to claim 4, further comprising:
an adjustment optical system including a first optical element and a second optical element that function as lenses, wherein
the first optical element and the second optical element are arranged such that a wavefront shape of the laser light in the spatial light modulator similarly coincides with a wavefront shape of the laser light in the converging part, and the first optical element and the second optical element form a bilateral telecentric optical system, and
the first light blocking part is disposed on a Fourier plane between the first optical element and the second optical element.

6. The laser processing apparatus according to claim 5, wherein
the first light blocking part includes a pair of first portions facing each other in the Y direction, and
each of the pair of first portions is movable along the Y direction.

7. The laser processing apparatus according to claim 6, wherein
the control part determines a distance between the pair of first portions based on a shift amount between the first converging point and the second converging point in the Y direction, and controls the first light blocking part such that the pair of first portions face each other with the determined distance in the Y direction.

8. The laser processing apparatus according to claim 5, wherein
the first light blocking part includes a pair of second portions facing each other in the X direction.

9. The laser processing apparatus according to claim 4, further comprising:
a second light blocking part configured to block 0th order light and/or non-modulated light, wherein
the second light blocking part is movable forward and backward with respect to an optical path of the 0th order light and/or an optical path of the non-modulated light.

10. A laser processing method performed in a laser processing apparatus including
a support part configured to support an object,
a light source configured to emit laser light,
a spatial light modulator configured to modulate the laser light emitted from the light source,
a converging part configured to converge the laser light modulated by the spatial light modulator on the object from one side in a Z direction, and
a moving part configured to move the converging part relative to the support part, the laser processing method comprising:
a first step of controlling the spatial light modulator such that the laser light is branched into first processing light and second processing light; and
a second step of controlling the moving part such that a first converging point of the first processing light and a second converging point of the second processing light relatively move along a first line and a second line in the object, wherein
in the first step, when a relative movement direction of the first converging point and the second converging point is set to an X direction, and a direction perpendicular to the Z direction and the X direction is set to a Y direction, the spatial light modulator is controlled such that the first converging point and the second converging point are shifted from each other in each of the X direction and the Y direction.
